(19) United States
(12) Patent Application Publication
(10) Pub. No.: US 2007/0196983 A1
(43) Pub. Date: Aug. 23, 2007

(54) Method of manufacturing non-volatile memory device

(75) Inventor: Young Ok Hong, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/648,440

(22) Filed: Dec. 29, 2006

(30) Foreign Application Priority Data
Feb. 22, 2006 (KR) 2006-17234
May 29, 2006 (KR) 2006-48221
Dec. 4, 2006 (KR) 2006-121444

(51) Int. Cl. H01L 21/336

(52) U.S. Cl. 438/257

(57) ABSTRACT

A method of manufacturing a non-volatile memory device includes the steps of providing a semiconductor substrate in which a tunnel insulating layer and a charge storage layer are formed in an active region, and an isolation layer is formed in an isolation region, forming a dielectric layer over the semiconductor substrate including the charge storage layer, etching the dielectric layer, the charge storage layer, and a portion of the tunnel insulating layer so that the semiconductor substrate is exposed, thus forming a contact hole, forming a first junction region in the exposed semiconductor substrate, forming a conductive layer for a control gate over the semiconductor substrate, including the first junction region, so that the contact hole is filled, and patterning the conductive layer, the dielectric layer, and the charge storage layer to form select lines and word lines, and at the same time, forming a contact plug on the first junction region.

### CROSS-REFERENCE TO RELATED APPLICATIONS

The priority of Korean patent application 10-2006-17234 filed Feb. 22, 2006, and Korean patent application 10-2006-48221 filed May 29, 2006, and Korean patent application 10-2006-121444 flied Dec. 4, 2006 which are incorporated by reference in their entirety, is hereby claimed.

### BACKGROUND OF THE INVENTION

1. Field of the Invention

The invention relates to non-volatile memory devices and, more particularly, to a method of manufacturing a non-volatile memory device, which can be applied to the manufacture process of a NAND flash memory device.

2. Related Technology

One representative type of non-volatile memory device is a flash memory device. Active research has been done into Silicon/Oxide/Nitride/Oxide/Silicon (SONOS) type flash memory in which a floating gate of a flash memory device is formed from insulating material, such as a nitride layer, rather than conductive material, such as polysilicon.

The SONOS type flash memory device generally has a structure in which an oxide layer, a nitride layer, an oxide layer, and a polycrystalline silicon layer are sequentially laminated on a semiconductor substrate. The lower oxide layer serves as a tunnel insulating layer, and the nitride layer serves as a charge storage layer for storing charges, i.e., a floating gate. An upper oxide layer formed on the nitride layer serves to provide insulation between the charge storage layer and a control gate.

FIG. 1 is a cross-sectional view of a conventional flash memory device.

Referring to FIG. 1, in a conventional flash memory device, a tunnel insulating layer 102, a source select line SSL including a charge storage layer 104, a dielectric layer 106, and a conductive layer 112 for a control gate, word lines (not shown), and a drain select line (not shown) are formed over a semiconductor substrate 100. A junction region 110 is formed between the word lines and select lines. The junction region formed between the source select lines SSL become a common source CS. An insulating layer 118 is formed on the entire surface of the resulting structure. The insulating layer on the common source CS is etched, and the etched region is filled with conductive material, forming a common source plug CSP.

In a general flash memory device, the charge storage layer 104 can be formed from polysilicon, and in a flash memory device of the SONOS structure, the charge storage layer 104 can be formed from a nitride layer. In a similar way, in a general flash memory device, the dielectric layer 106 can be formed from an ONO structure, and in a flash memory device of the SONOS structure, the dielectric layer 106 can be formed from an aluminum oxide layer. In FIG. 1, reference numeral 114 indicates a hard mask.

In the flash memory device, a drain (not shown) is formed between the drain select lines (not shown), and the common source CS is formed between the source select lines SSL. Thus, as the level of integration of devices increases, it is difficult to secure overlay margin with the neighboring select line in forming a source contact plug or a drain contact plug, such as a common source plug. It is also difficult to secure a good breakdown voltage between the drain select line and the drain contact plug. Consequently, a distance between the drain select lines is widened, making it difficult to increase the level of integration of devices.

Furthermore, in order to form the common source plug (CSP), several processes including chemical mechanical polishing (CMP) processes must be performed. Meanwhile, in order to electrically insulate the common source plug CSP and bit lines formed subsequently, an interlayer insulating layer has to be additionally formed after the common source plug CSP is formed. The depth of a drain contact hole, which is formed subsequently, is deepened due to the addition of the interlayer insulating layer. If the depth of the drain contact hole is deepened, the margin of a contact etch process is decreased, resulting in damage to the top surface of the contact hole, and a bridge between neighboring contact plugs is caused. Furthermore, the width of the bottom of the contact hole is narrowed, or the insulating layer remains, so that the drain contact plug and the drain may not be electrically connected. In order to prevent the problem, the thickness of the interlayer insulating layer must be reduced. It is, however, difficult to reduce the thickness of the interlayer insulating layer when considering an electrical connection or parasitic capacitance between the bit lines and the common source plug CSP.

### BRIEF SUMMARY OF THE INVENTION

The invention provides a method of manufacturing a non-volatile memory device, in which a common source plug formed on a common source or a portion of a drain contact plug formed on a drain are formed together with word lines and select line, thus preventing the occurrence of alignment error, reducing the process step, and improving the reliability of a process.

In one embodiment, a method of manufacturing a non-volatile memory device includes the steps of forming a tunnel insulating layer, a charge storage layer and a dielectric layer over the semiconductor substrate, etching a part of the dielectric layer, the charge storage layer, and the tunnel insulating layer to form a contact hole exposing the semiconductor substrate, forming a first junction region in the exposed semiconductor substrate, forming a control gate over the dielectric layer to form a cell gate and the first junction region to fill the contact hole, and patterning the conductive layer, the dielectric layer and the charge storage layer to form select lines and word lines, and a contact plug.

In another embodiment, a method of manufacturing a non-volatile memory device includes the steps of forming a tunnel insulating layer, a charge storage layer and a dielectric layer over a semiconductor substrate including the charge storage layer, etching a part of the dielectric layer, the charge storage layer, and the tunnel insulating layer, to form contact holes in a common source region and a drain region, forming a first junction region in the semiconductor substrate to expose the contact holes, forming a control gate over the dielectric layer to form a cell gate and the first junction region to fill the contact hole, and patterning control gate, the dielectric layer, and the charge storage layer to form select lines and word lines, and a common source plug and a drain plug.

### BRIEF DESCRIPTION OF THE DRAWINGS

FIG. 1 is a cross-sectional view of a conventional flash memory device.

FIGS. 2A to 2G are cross-sectional views illustrating a method of manufacturing a non-volatile memory device according to a first embodiment of the invention.

FIGS. 3A to 3G are cross-sectional views illustrating a method of manufacturing a non-volatile memory device according to a second embodiment of the invention.

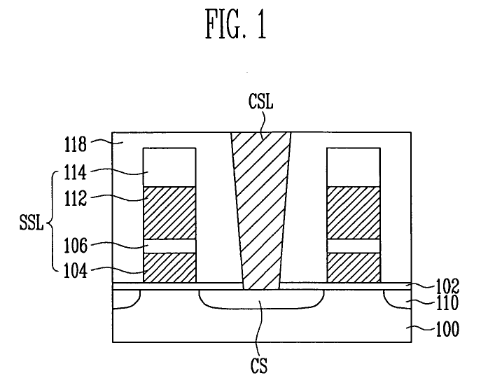

### DESCRIPTION OF SPECIFIC EMBODIMENTS

Specific embodiments according to the invention are described below with reference to the accompanying drawings.

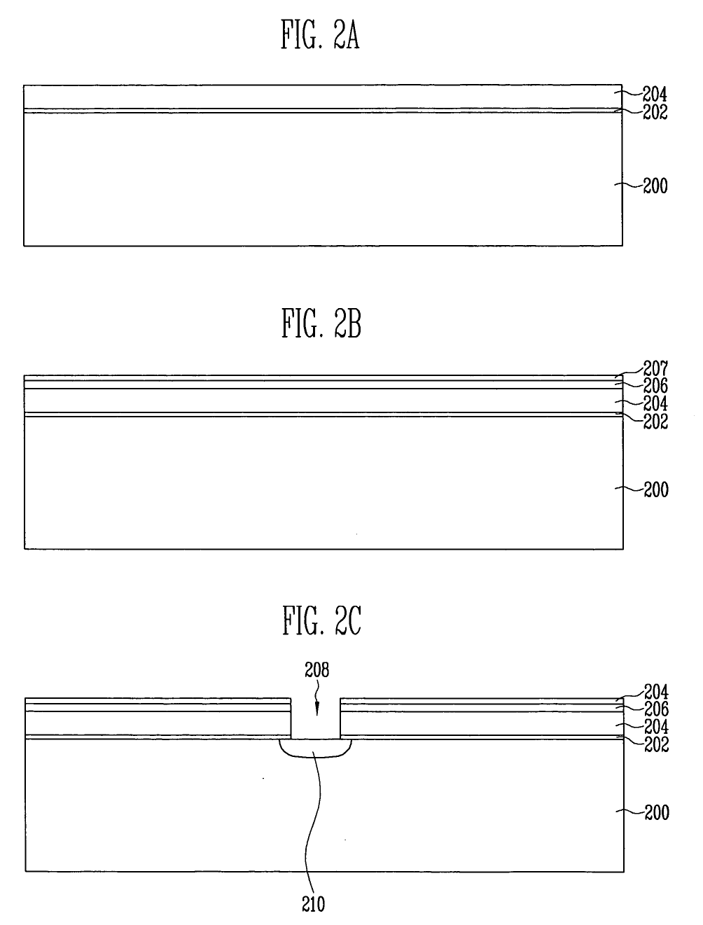

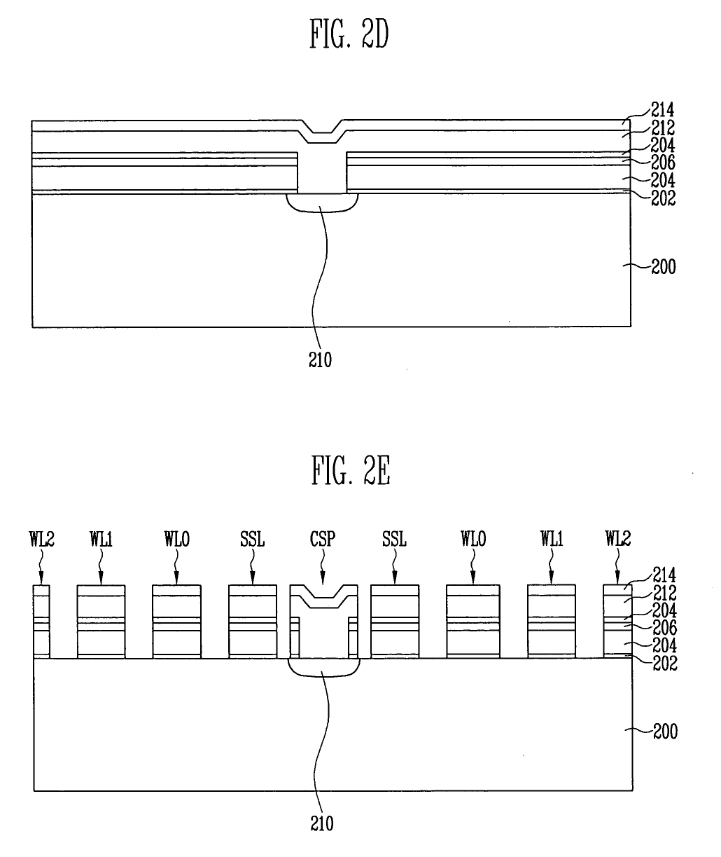

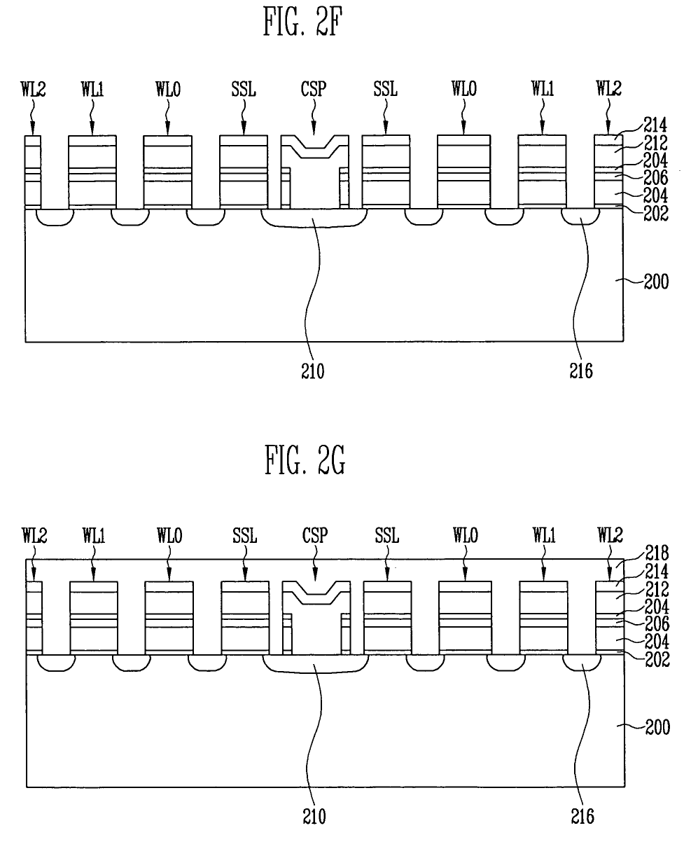

FIGS. 2A to 2G are cross-sectional views illustrating a method of manufacturing a non-volatile memory device according to a first embodiment of the invention.

Referring to FIG. 2A, a tunnel insulating layer 202 and a charge storage layer 204 are sequentially formed over a semiconductor substrate 200. In a general flash memory device, the charge storage layer 204 can be formed from polysilicon, and in a flash memory device of the SONOS structure, the charge storage layer 204 is preferably formed from a nitride layer.

In a general flash memory device, an isolation mask (not shown) is formed on the charge storage layer 204. The charge storage layer 204, the tunnel insulating layer 202, and the semiconductor substrate 200 are etched by an etch process employing the isolation mask, thus forming a trench in the isolation region. The trench is filled with insulating material to form an isolation layer. The isolation mask is then removed.

Meanwhile, in a flash memory device of the SONOS structure, before the tunnel insulating layer 202 and the charge storage layer 204 are formed, the isolation layer (not shown) can be formed in the isolation region. Further, a gate insulating layer (not shown) and a gate conductive layer (not shown) for forming transistors as well as the isolation layer can be further formed in a peri region (not shown). FIG. 2A is a cross-sectional view of the active region located between the isolation regions. Thus, the active region is not seen although the isolation layer is first formed.

Referring to FIG. 2B, a dielectric layer 206 is formed on the entire surface of the resulting structure including the charge storage layer 204. The dielectric layer 206 functions to electrically insulate a conductive layer for a control gate, which will be formed in a subsequent process, and the charge storage layer 204. In a general flash memory device, the dielectric layer 206 can have the ONO structure, and in a flash memory device of the SONOS structure, the dielectric layer 206 is preferably formed from an aluminum oxide layer.

Meanwhile, in a flash memory device of the SONOS structure, a capping layer 207 is formed on the dielectric layer 206. The capping layer 207 is used as an etch mask at the time of an etch process of removing a portion of the dielectric layer 206 from the peri region (not shown). The capping layer 207 can be formed from polysilicon. Accordingly, in a general flash memory device, the step of forming the capping layer 207 may be omitted.

Referring to FIG. 2C, the capping layer 207, the dielectric layer 206, the charge storage layer 204, and the tunnel insulating layer 202 of a region in which a contact plug (a common source plug or a drain contact plug) will be formed are removed to form a contact hole 208. The contact hole 208 can have a width, which is wider or narrower than or the same as that of a contact plug that will be formed in a subsequent process. A portion of the semiconductor substrate 200 is thereby exposed.

Thereafter, an impurity is implanted into the exposed semiconductor substrate 200 to form a first junction region 210. The first junction region 210 is preferably formed by implanting an N type impurity. It is preferred that the N type impurity be implanted at a high concentration in order to obtain an ohmic contact when the contact plug is formed from a metal layer in a subsequent process. The impurity implanted to form the first junction region 210 is diffused into both sides, so that the width of the first junction region 210 becomes wider than that of the contact hole 208. If the first junction region 210 is formed in a region in which the common source plug will be formed, the first junction region 210 becomes a portion of the common source. If the first junction region 210 is formed in a region in which the drain contact plug will be formed, the first junction region 210 becomes a portion of the drain. This is described in detail below.

Referring to FIG. 2D, a conductive layer 212 for a control gate and a hard mask pattern 214 are sequentially formed on the entire surface of the resulting structure including the first junction region 210. The conductive layer 212 is preferably formed to have a lamination structure of a polysilicon layer and a silicide layer, or can be formed using only a metal layer. In the latter case, the metal layer is preferably formed from tungsten.

Referring to FIG. 2E, the conductive layer 212, the capping layer 207, the dielectric layer 206 and the charge storage layer 204 are patterned by means of an etch process employing the hard mask pattern 214, thus forming a drain select line (not shown), a plurality of word lines WL0 to WL2 (for convenience, only every three word lines are illustrated), and a contact plug between the select lines along with the source select line SSL at the same time. The contact plug is formed on the first junction region 210. At this time, in FIG. 2C, if the first junction region 210 is formed in a region in which the common source plug will be formed, the contact plug becomes the common source plug CSP. Further, in the case where the first junction region 210 is formed in a region in which the drain contact plug will be formed, the contact plug becomes the drain contact plug.

FIG. 2E illustrates an example in which the first junction region 210 is formed in a region in which the common source plug will be formed, and the common source plug CSP is formed on the first junction region 210. The common source plug CSP (or the drain contact plug) can have a width wider than that of the contact hole (refer to 208 in FIG. 2C). In this case, a portion of the charge storage layer 204 and the dielectric layer 206 can be included at the edge of the common source plug CSP. If the width of the common source plug CSP is narrower than that of the contact hole, the common source plug CSP does not include the charge storage layer 204 and the dielectric layer 206, but includes only the conductive layer 212.

Referring to FIG. 2F, a second junction region 216 is formed in the semiconductor substrate 200 between the word lines WL0 to WL2, the select line SSL (the drain select line (not shown)) and the common source plug CSP by means of an ion implantation process. The second junction region 216 is preferably formed by implanting an N type impurity. The second junction region 216 formed between the select lines becomes the common source CS or the drain (not shown) together with the first junction region 210.

Referring to FIG. 2G, an interlayer insulating layer 218 is formed on the entire surface of the semiconductor substrate 200. As described above, in the present embodiment, the common source plug CSP or, the drain contact plug is formed together with the word lines WL0 to WL2 and the select lines. Accordingly, alignment error, which may occur in a process of forming the common source plug CSP subsequently, can be prevented.

Furthermore, in the prior art, the first interlayer insulating layer is formed in order to form the common source plug, and the second interlayer insulating layer is then formed in order to form the drain contact plug. In the present embodiment, however, only the interlayer insulating layer for forming the drain contact plug can be formed since the common source plug is formed together with the word lines and the select lines. Therefore, the process step can be reduced, an overall thickness of the interlayer insulating layer can be made thin, and an etch thickness when the drain contact hole is formed can be decreased.

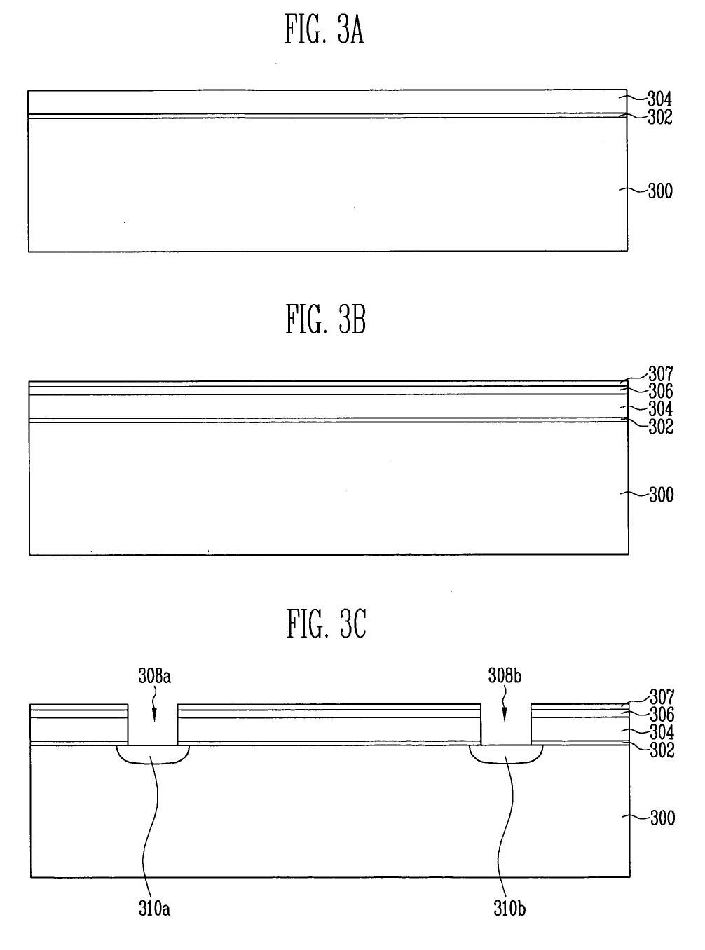

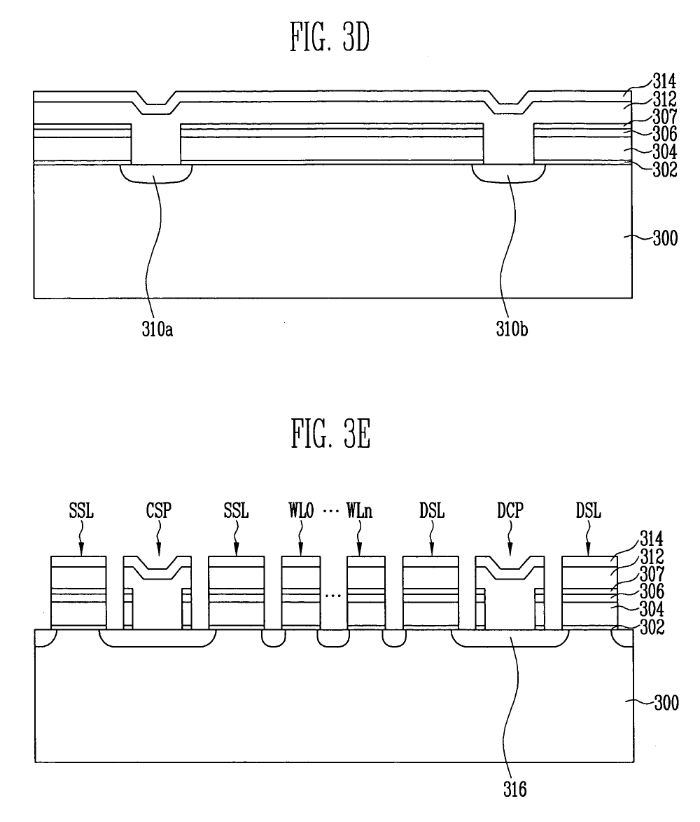

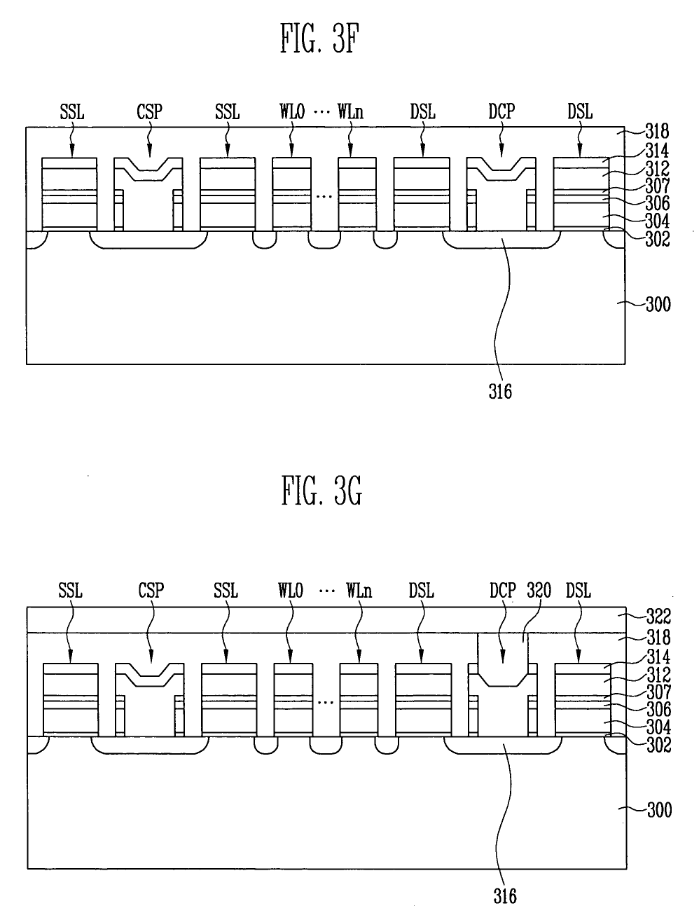

FIGS. 3A to 3G are cross-sectional views illustrating a method of manufacturing a non-volatile memory device according to a second embodiment of the invention.

Referring to FIG. 3A, a tunnel insulating layer 302 and a charge storage layer 304 are sequentially formed over a semiconductor substrate 300. In a general flash memory device, the charge storage layer 304 can be formed from polysilicon, and in a flash memory device of the SONOS structure, the charge storage layer 304 is preferably formed from a nitride layer.

In a general flash memory device, an isolation mask (not shown) is formed on the charge storage layer 304. The charge storage layer 304, the tunnel insulating layer 302 and the semiconductor substrate 300 are etched by an etch process employing the isolation mask, thus forming a trench in the isolation region. The trench is filled with insulating material to form an isolation layer. The isolation mask is then removed.

Meanwhile, in a flash memory device of the SONOS structure, before the tunnel insulating layer 302 and the charge storage layer 304 are formed, the isolation layer (not shown) is preferably formed in the isolation region. Further, a gate insulating layer (not shown) and a gate conductive layer (not shown) for forming transistors as well as the isolation layer is preferably further formed in a peri region (not shown). FIG. 3A is a cross-sectional view of the active region located between the isolation regions. Thus, the active region is not seen although the isolation layer is first formed.

Referring to FIG. 3B, a dielectric layer 306 is formed on the entire surface of the resulting structure including the charge storage layer 304. The dielectric layer 306 functions to electrically insulate a conductive layer for a control gate, which will be formed in a subsequent process, and the charge storage layer 304. In a general flash memory device, the dielectric layer 306 can have the ONO structure, and in a flash memory device of the SONOS structure, the dielectric layer 306 is preferably formed from an aluminum oxide layer.

Meanwhile, in a flash memory device of the SONOS structure, a capping layer 307 is formed on the dielectric layer 306. The capping layer 307 is used as an etch mask at the time of an etch process of removing a portion of the dielectric layer 306 from the peri region (not shown). The capping layer 307 is preferably formed from polysilicon. Accordingly, in a general flash memory device, the step of forming the capping layer 307 may be omitted.

Referring to FIG. 3C, the capping layer 307, the dielectric layer 306, the charge storage layer 304 and the tunnel insulating layer 302 of a region in which a common source drain) will be formed are removed to form contact holes 308a and 308b. Each of the contact holes 308a and 308b can have a width, which is wider or narrower than, or the same as that of a contact plug that will be formed in a subsequent process. A portion of the semiconductor substrate 300 is thereby exposed.

An impurity is then implanted into the exposed semiconductor substrate 300 to form first junction regions 310a and 310b. Each of the first junction regions 310a and 310b is preferably formed by implanting an N type impurity. It is preferable that the N type impurity be implanted at a high concentration in order to obtain an ohmic contact when the contact plug is formed from a metal layer in a subsequent process. The impurity implanted to form the first junction regions 310a and 310b is diffused into both sides, so that the width of each of the first junction regions 310a and 310b becomes wider than that of each of the contact holes 308a and 308b. The first junction region 310a formed in the common source region becomes a portion of the common source, and the first junction region 310b formed in the drain region becomes a portion of the drain. This is described in detail below.

Referring to FIG. 3D, a conductive layer 312 for a control gate and a hard mask pattern 314 are sequentially formed on the entire surface of the resulting structure including the first junction regions 310a and 310b. The conductive layer 312 preferably has a lamination structure of a polysilicon layer and a silicide layer, or can be formed using only a metal layer. The metal layer is preferably formed from tungsten.

The conductive layer 312, the capping layer 307, the dielectric layer 306 and the charge storage layer 304 are patterned by means of an etch process employing the hard mask pattern 314, thus forming a drain select line DSL, a plurality of word lines WL0 to WLn and source select lines SSL. At this time, a common source plug CSP is formed on the first junction region 310a between the source select lines SSL. A drain contact plug DCP is also formed on the first junction region 310b between the drain select lines DSL. In the first embodiment, an example in which the common source plug CSP or the drain contact plug is formed has been described. However, FIG. 3E illustrates an example in which the common source plug CSP and the drain contact plug DCP are formed at the same time.

The width of the common source plug CSP or the drain contact plug DCP can be wider than that of each of the contact holes (refer to 308a and 308b in FIG. 3C). In this case, the charge storage layer 304 and the dielectric layer 306 can be partially included at the edge of the common source plug CSP or the drain contact plug DCP. If the width of the common source plug CSP or the drain contact plug DCP is narrower than that of the contact hole, the charge storage layer 304 and the dielectric layer 306 may not be included in the common source plug CSP or the drain contact plug DCP, but only the conductive layer 312 may be included in the common source plug CSP or the drain contact plug DCP.

Thereafter, a second junction region 316 is formed in the semiconductor substrate 230 between the word lines WL0 to WLn, the select lines SSL and DSL, the common source plug CSP and the drain contact plug DCP preferably by means of an ion implantation process. The second junction region 216 can be formed by implanting an N type impurity. The second junction region 316 formed between the source select lines SSL becomes the common source CS along with the first junction region 310a. Furthermore, the second junction region 316 formed between the drain contact plugs DCP becomes a drain along with the first junction region 310b.

Referring to FIG. 3F, an interlayer insulating layer 318 is formed on the entire surface of the resulting structure including the semiconductor substrate 300. In order to reduce the step generated by underlying structures, a Chemical Mechanical Polishing (CMP) process is preferably performed on the interlayer insulating layer 318.

Referring to FIG. 3G, after the interlayer insulating layer 318 and the hard mask pattern 314 on the drain contact plug DCP are partially removed, the removed portions are filled with a conductive material to form an upper drain contact plug 320. A bit line 322 connected to the upper drain contact plug 320 is formed on the interlayer insulating layer 318.

As described above, in the present embodiment, the common source plug CSP and the drain contact plug DCP are formed together with the word lines WL0 to WLn and the select lines DSL and SSL. Accordingly, alignment error, which may occur in a process of subsequently forming the common source plug CSP or the drain contact plug DCP, can be prevented.

Furthermore, in the prior art, the first interlayer insulating layer is formed in order to form the common source plug, and the second interlayer insulating layer is then formed in order to form the drain contact plug. In the present embodiment, however, the common source plug is formed simultaneously with the word lines and the select lines. Thus, only the interlayer insulating layer 318 for forming the upper drain contact plug can be formed. Therefore, the number of process steps can be reduced, an overall thickness of the interlayer insulating layer can be reduced, and an etch thickness when the upper drain contact hole is formed can be decreased.

As described above, in accordance with the invention, the common source plug formed on the common source or a portion of the drain contact plug formed on the drain is formed together with the word lines and the select lines. Accordingly, the occurrence of alignment error can be prevented, the number of process steps can be decreased, and the reliability of the process can be improved.

The disclosed embodiments of the invention are illustrative and not limiting. Various alternatives and equivalents are possible. Other additions, subtractions, or modifications are intended to fall within the scope of the appended claims.

What is claimed is:

1. A method of manufacturing a non-volatile memory device, the method comprising the steps of:
forming a tunnel insulating layer, a charge storage layer and a dielectric layer over a semiconductor substrate;
etching a part of the dielectric layer, the charge storage layer, and the tunnel insulating layer to form a contact hole exposing the semiconductor substrate;
forming a first junction region in the exposed semiconductor substrate;
forming a control gate over the dielectric layer to form a cell gate and the first junction region to fill the contact hole; and
patterning the conductive layer, the dielectric layer and the charge storage layer to form select lines and word lines, and a contact plug.

2. The method of claim 1, further comprising the step of, after forming the contact plug, forming a second junction region in the semiconductor substrate between the word lines, the select lines, and the contact plug.

3. The method of claim 2, wherein an impurity concentration of the first junction region is higher than that of the second junction region.

4. The method of claim 1, comprising forming the first junction region in a common source region, wherein the contact plug becomes a common source plug.

5. The method of claim 1, comprising forming the first junction region in a drain region, wherein the contact plug becomes a drain contact plug.

6. The method of claim 1, comprising forming the charge storage layer from polysilicon.

7. The method of claim 1, comprising forming the charge storage layer from a nitride layer.

8. The method of claim 1, wherein the dielectric layer has an ONO structure.

9. The method of claim 1, comprising forming the dielectric layer from an aluminum oxide layer.

10. A method of manufacturing a non-volatile memory device, the method comprising the steps of:
forming a tunnel insulating layer, a charge storage layer and a dielectric layer over a semiconductor substrate including the charge storage layer;
etching a part of the dielectric layer, the charge storage layer, and the tunnel insulating layer, to form contact holes in a common source region and a drain region;
forming a first junction region in the semiconductor substrate to expose the contact holes;
forming a control gate over the dielectric layer to form a cell gate and the first junction region to fill the contact hole; and
patterning control gate, the dielectric layer, and the charge storage layer to form select lines and word lines, and a common source plug and a drain plug.

11. The method of claim 10, further comprising, after forming the common source plug and the drain contact plug; and
forming a second junction region in the semiconductor substrate between the word lines, the select lines, the common source plug, and the drain contact plug.

12. The method of claim 11, wherein an impurity concentration of the first junction region is higher than that of the second junction region.

13. The method of claim 10, further comprising:
after forming the common source plug and the drain contact plug,
forming an interlayer insulating layer over cell gate, the common source plug and the drain contact plug;
forming a second contact hole to expose the drain contact plug; and
filling the second contact hole with conductive material.

14. The method of claim 10, comprising forming the charge storage layer from polysilicon.

15. The method of claim 10, comprising forming the charge storage layer from a nitride layer.

16. The method of claim 10, wherein the dielectric layer has an ONO structure.

17. The method of claim 10, comprising forming the dielectric layer from an aluminum oxide layer.

18. The method of claim 10, further comprising the step of forming a capping layer over the dielectric layer.

19. The method of claim 18, comprising forming the capping layer from polysilicon.
